(19) United States
(12) Patent Application Publication
(10) Pub. No.: US 2015/0333206 A1
(43) Pub. Date: Nov. 19, 2015

(54) MULTILAYER SHEET, ENCAPSULANT FOR SOLAR CELL ELEMENT, AND SOLAR CELL MODULE

(71) Applicant: Du Pont-Mitsui Polychemicals Co., Ltd., Tokyo (JP)

(72) Inventor: Koichi Nishijima, Ichihara-shi (JP)

(21) Appl. No.: 14/789,399

(22) Filed: Jul. 1, 2015

Related U.S. Application Data
(62) Division of application No. 13/126,177, filed on Apr. 27, 2011.

(30) Foreign Application Priority Data
Oct. 30, 2008 (JP) 2008-280518

(51) Int. Cl. H01L 31/048; B32B 27/30; B32B 27/08; B32B 27/18; B32B 27/32

(52) U.S. Cl. CPC H01L 31/0481; B32B 27/18; B32B 27/32; B32B 27/08; B32B 27/308; B32B 2457/12; B32B 2250/03; B32B 2250/40

(57) ABSTRACT

A multilayer sheet including an (A) layer containing an ethylene type zinc ionomer as a main component and a silane coupling agent, and a (B) layer containing a polyethylene-based copolymer with a melting point of 90° C. or higher as a main component and a silane coupling agent having a content ratio with respect to the resin material that is lower than a content ratio of the silane coupling agent with respect to resin material in the (A) layer, wherein the total thickness of the (A) layer and the (B) layer is from 0.1 to 2 mm. Such multilayer sheet may be superior in adhesive strength, durability and heat resistance, and obtained at a suppressed cost.

### TECHNICAL FIELD

The present invention relates to a multilayer sheet and an encapsulant for solar cell element suitable for constituting a solar cell module, as well as a solar cell module utilizing the same.

### BACKGROUND ART

Hydroelectric power generation, wind power generation, photovoltaic power generation and the like, which can be used to attempt to reduce carbon dioxide or improve other environmental problems by using inexhaustible natural energy, have received much attention. Among these, photovoltaic power generation has seen a remarkable improvement in performance such as the power generation efficiency of solar cell modules, and an ongoing decrease in price, and national and local governments have worked on projects to promote the introduction of residential photovoltaic power generation systems. Thus, in recent years, the spread of photovoltaic power generation systems has advanced considerably.

By photovoltaic power generation, solar light energy is converted directly to electric energy using a semiconductor (solar cell element), such as a silicon cell. The performance of the solar cell element utilized there is deteriorated by contacting the outside air. Consequently, the solar cell element is sandwiched by an encapsulant or a protective film for providing buffering and prevention of contamination with a foreign substance or penetration of moisture.

For a sheet to be used as an encapsulant, a cross-linked ethylene/vinyl acetate copolymer, whose vinyl acetate content is from 25% to 33% by mass, is generally used from viewpoints of transparency, flexibility, processability, and durability (see, for example, Patent Document 1). Meanwhile, in case the vinyl acetate content of an ethylene/vinyl acetate copolymer becomes higher, higher becomes the moisture permeability thereof. In case the moisture permeability becomes higher, depending on the type or the adhesion condition of an upper transparent protective material or a back sheet, the adhesive property with the upper transparent protective material or the back sheet may be deteriorated. Therefore, a back sheet having high barrier is utilized and furthermore a butyl rubber having high barrier is utilized to seal the circumference of a module aiming for preventing moisture.

As a countermeasure, an alternative material for a sheet for encapsulant of the solar cell has been studied. More particularly, an encapsulant for solar cell element, and a solar cell sealing sheet therewith, the material being made of an ethylene/unsaturated carboxylic acid copolymer or an ionomer thereof, with the content of the unsaturated carboxylic acid of 4% by mass or higher and the melting point of 85° C. or higher, and not inducing moisture permeation, moisture absorption, or acetic acid elimination, have been proposed (see, for example, Patent Documents 2 and 3).

### PRIOR ART DOCUMENTS

### Patent Document

Patent Document 1: Japanese Patent Publication No. 62-14111

Patent Document 2: Japanese Patent Laid-Open No. 2000-186114

Patent Document 3: Japanese Patent Laid-Open No. 2006-352789

### DISCLOSURE OF THE INVENTION

### Problem to be Solved by the Invention

However, along with the growth of solar cells, further improvement of performances, such as adhesive property, durability, heat resistance, and the like, has become demanded.

For further growth of solar cells, it is very important to supply solar cell modules at a low price range in addition to good performances. Thereby, it is necessary to supply components of a solar cell module at a low price. For example, in case of an encapsulant composed of the aforedescribed ethylene/unsaturated carboxylic acid copolymer or ionomer, generally a silane coupling agent is added for improving adhesive property with an upper transparent protective material or a lower protective material. However the use of a silane coupling agent makes the cost of raw materials constituting an encapsulant high. Consequently, it is desirable to curtail the consumption of a silane coupling agent to the extent possible.

The present invention has been attempted under such circumstances. Namely, a multilayer sheet and an encapsulant for solar cell element (for example, sealing sheet for solar cell), which utilize an ethylene/unsaturated carboxylic acid copolymer or an ionomer thereof, are superior in adhesive strength, durability and heat resistance, and may curtail the consumption of a silane coupling agent, have been demanded. Further, a solar cell module to be supplied at a low price has been demanded.

### Means for Solving the Problem

The present inventors intensively studied a technology, which may solve the problem to improve various performances of a multilayer sheet, while keeping the cost low, thereby completing the present invention. Specific measures to attain the object are as follows.

Specifically, the present invention includes the following aspects.

[1] An aspect is a multilayer sheet comprising an (A) layer comprising an ethylene type zinc ionomer as a main component and a silane coupling agent, and a (B) layer comprising a polyethylene-based copolymer with a melting point of 90° C. or higher as a main component, wherein the total thickness of the (A) layer and the (B) layer is 0.1 to 2 mm, provided that the content ratio of a silane coupling agent in the (B) layer with respect to the resin material (including the polyethylene-based copolymer) is lower than the content ratio of the silane coupling agent in the (A) layer with respect to the resin material (including the ethylene type zinc ionomer).

[2] The multilayer sheet is preferably a multilayer sheet as described in [1] above, wherein the (B) layer contains substantially no silane coupling agent.

[3] The multilayer sheet is preferably a multilayer sheet as described in [1] or [2] above having a three-layer structure comprising two layers of the (A) layer comprising the ethylene type zinc ionomer as a main component and the (B) layer comprising a polyethylene-based copolymer with a melting point of 90° C. or higher as a main component disposed between the two (A) layers.

[4] The multilayer sheet is preferably a multilayer sheet as described in any one of the above [1] to [3], wherein the ethylene type zinc ionomer in the (A) layer comprises an ionomer and a dialkoxy silane having an amino group in an amount of 3 parts by mass or less with respect to 100 parts by mass of the ionomer.

[5] The multilayer sheet is preferably a multilayer sheet as described in any one of the above [1] to [4], wherein the ratio (a/b) of the thickness (a) of the (A) layer to the thickness (b) of the (B) layer is from 20/1 to 1/20.

[6] The multilayer sheet is preferably a multilayer sheet as described in any one of the above [1] to [5], wherein the melt flow rates (MFR: RS K7210-1999, 190° C., load 2160 g) of the ethylene type zinc ionomer in the (A) layer and of the polyethylene-based copolymer with the melting point of 90° C. or higher in the (B) layer is from 0.1 to 150 g/10 min.

[7] The multilayer sheet is preferably a multilayer sheet as described in any one of the above [1] to [6], wherein at least one of the (A) layer and the (B) layer further comprises one or more additives selected from an ultraviolet absorber, a light stabilizer, and an antioxidant.

[8] The multilayer sheet is preferably a multilayer sheet as described in any one of the above [1] to [7], wherein the ethylene type zinc ionomer is a zinc ionomer of an ethylene/unsaturated carboxylic acid copolymer having a constituent unit derived from ethylene and a constituent unit derived from an unsaturated carboxylic acid, wherein the content ratio of the constituent unit derived from ethylene is 75% to 95% by mass, and the content ratio of the constituent unit derived from an unsaturated carboxylic acid is from 5 to 25% by mass.

[9] The multilayer sheet is preferably a multilayer sheet as described in [8] above, wherein the unsaturated carboxylic acid is acrylic acid or methacrylic acid.

[10] The multilayer sheet is preferably a multilayer sheet as described in any one of the above [1] to [9], wherein the degree of neutralization of the ethylene type zinc ionomer is from 5% to 60%.

[11] The multilayer sheet is preferably a multilayer sheet as described in any one of the above [1] to [10], wherein the silane coupling agent is at least one selected from N-(2-aminoethyl)-3-aminopropylmethyldimethoxysilane, N-(2-aminoethyl)-3-aminopropylmethyldiethoxysilane, N-(2-aminoethyl)-3-aminopropylethyldimethoxy silane, 3-aminopropylmethyldimethoxysilane, and 3-aminopropylmethyldiethoxysilane.

[12] The multilayer sheet is preferably a multilayer sheet as described in any one of the above [1] to [11], wherein the (A) layer contains the silane coupling agent in an amount range of from 0.03 to 3 parts by mass with respect to 100 parts by mass of the ethylene type zinc ionomer.

[13] The multilayer sheet is preferably a multilayer sheet as described in any one of the above [1] to [12], wherein the polyethylene-based copolymer is an ethylene/unsaturated carboxylic acid copolymer or an ionomer thereof

[14] The multilayer sheet is preferably a multilayer sheet as described in [13] above, wherein the ionomer of an ethylene/unsaturated carboxylic acid copolymer is a zinc ionomer of an ethylene/acrylic acid copolymer or an ethylene/methacrylic acid copolymer.

[15] Another aspect is an encapsulant for solar cell element including the multilayer sheet as described in any one of the above [1] to [14].

[16] Another aspect is a solar cell module formed by using the multilayer sheet as described in any one of the above [1] to [14].

### Effect Of The Invention

According to the present invention, a multilayer sheet and an encapsulant for solar cell element (for example, sealing sheet for solar cell), which utilize an ethylene/unsaturated carboxylic acid copolymer or an ionomer thereof, are superior in adhesive strength, durability and heat resistance, and may curtail the consumption of a silane coupling agent, may be provided. Further, a solar cell module to be supplied at a low price may be provided.

Since the the multilayer sheet may be used without cross-linking, as required for a conventional ethylene/vinyl acetate copolymer, a cross-linking step may be omitted in a production process for a solar cell module, thereby solar cell module may be supplied at a low price.

### BEST MODE FOR CARRYING OUT THE INVENTION

[Multilayer Sheet and Encapsulant for Solar Cell Element]

A multilayer sheet of the present invention is so constituted that it includes an (A) layer containing an ethylene type zinc ionomer as a main component and a (B) layer containing a polyethylene-based copolymer with a melting point of 90° C. or higher as a main component, that at least the (A) layer of the (A) layer and the (B) layer further contains a silane coupling agent, and that the total thickness of the (A) layer and the (B) layer is from 0.1mm to 2 mm. However, the same is so constituted that the content ratio of the silane coupling agent with respect to the resin material in the (A) layer is higher than the content ratio of the silane coupling agent with respect to the resin material in the (B) layer.

The (A) layer constituting a multilayer sheet according to the present invention contains as a resin material at least one of ethylene type zinc ionomer as the main component, as well as at least one of silane coupling agent. The expression “contains . . . as the main component” means herein that the ratio occupied by “the ethylene type zinc ionomer” is 60% by mass or more with respect to the total mass of the (A) layer.

The ethylene type zinc ionomer, which is the main component of the (A) layer, is a zinc ionomer of an ethylene/unsaturated carboxylic acid copolymer having a constituent unit derived from ethylene and a constituent unit derived from an unsaturated carboxylic acid. The content ratio of the constituent unit derived from ethylene in an ethylene/unsaturated carboxylic acid copolymer, the base polymer, is preferably from 75% to 97% by mass and more, preferably from 75% to 95% by mass. The content ratio of the constituent unit derived from an unsaturated carboxylic acid is preferably from 3% to 25% by mass and more, preferably from 5% to 25% by mass.

In case the content ratio of the constituent unit derived from ethylene is 75% by mass or more, the copolymer exhibits good heat resistance, mechanical strength, and the like. On the other hand, in case the content ratio of the constituent unit derived from ethylene is 97% by mass or less, the adhesive property and the like are superior.

As the unsaturated carboxylic acid are preferable acrylic acid, methacrylic acid, maleic acid, maleic anhydride, maleic anhydride monoester and the like, and especially preferable is acrylic acid or methacrylic acid.

A zinc ionomer of an ethylene/acrylic acid copolymer, and a zinc ionomer of an ethylene/methacrylic acid copolymer are especially preferable examples of the ethylene type zinc ionomer.

Concerning the ethylene type zinc ionomer, a constituent unit derived from an unsaturated carboxylic acid in the ethylene/unsaturated carboxylic acid copolymer, which is a base polymer, plays an important role with respect to the adhesive property with a substrate such as glass. In case the content ratio of the constituent unit derived from an unsaturated carboxylic acid is 3% by mass or more, the transparency and flexibility are superior. Further, in case the content ratio of the constituent unit derived from an unsaturated carboxylic acid is 25% by mass or less, the stickiness is suppressed and the processability is superior.

In the ethylene/unsaturated carboxylic acid copolymer may be contained a constituent unit derived from another copolymerizable monomer in an amount of more than 0% by mass and 30% by mass or less, and preferably more than 0% by mass and 25% by mass or less, with respect to the total 100% by mass of ethylene and an unsaturated carboxylic acid. Examples of other copolymerizable monomer include an unsaturated ester, such as a vinyl ester (for example vinyl acetate and vinyl propionate) and a (meth)acrylic acid ester (for example methyl acrylate, ethyl acrylate, isobutyl acrylate, n-butyl acrylate, 2-ethylhexyl acrylate, methyl methacrylate and isobutyl methacrylate). In case a constituent unit derived from such other copolymer monomer is contained in the above described range, the flexibility of the ethylene/unsaturated carboxylic acid copolymer is favorably improved.

The ionomer with the degree of neutralization of normally 80% or less, and preferably from 5% to 80% is used. From viewpoints of processability and flexibility, the ionomer with the degree of neutralization of from 5% to 60%, especially from 5% to 30% is preferably used.

An ethylene/unsaturated carboxylic acid copolymer, which is a base polymer for the ethylene type zinc ionomer, may be produced by a radical copolymerization of its respective polymerization components at a high temperature and a high pressure. Its ionomer may be produced by reacting such ethylene/unsaturated carboxylic acid copolymer with zinc oxide, zinc acetate and the like.

Preferably is used the ethylene type zinc ionomer with the melt flow rate (according to MFR: JIS K7210-1999, 190° C., load 2160 g) of from 0.1 to 150 g/10 min, especially from 0.1 to 50 g/10 min, in case of considering the processability and mechanical strength.

Although there is no particular restriction on the melting point of an ethylene type zinc ionomer, the ethylene type zinc ionomer with the melting point of 90° C. or higher, especially 95° C. or higher is preferable, because the heat resistance become good.

The (A) layer constituting a multilayer sheet according to the present invention should preferably contain an ethylene type zinc ionomer in an amount of 60% by mass or more, more preferably 70% by mass or more, based on the solid substance in the layer. It is preferable that the content of an ethylene type zinc ionomer is in the aforedescribed range because transparency, adhesive property, durability and the like become good.

In case the (A) layer is not composed 100% by mass of an ethylene type zinc ionomer, any resin material to be mixed together with the ethylene type zinc ionomer may be used, insofar as it is well compatible with the ethylene type zinc ionomer and does not impair the transparency and mechanical property. Among others, an ethylene/unsaturated carboxylic acid copolymer, and an ethylene/unsaturated ester/unsaturated carboxylic acid copolymer are preferable. In case a resin material to be mixed together with an ethylene type zinc ionomer is a resin material having the melting point higher than the ethylene type zinc ionomer, the heat resistance and durability of the (A) layer may be improved.

At least the (A) layer of an (A) layer and a (B) layer in a multilayer sheet according to the present invention contains at least one of silane coupling agent. The (B) layer may also contain a silane coupling agent together with the (A) layer.

Examples of the silane coupling agent include γ-methacryloxypropyltrimethoxysilane, γ-methacryloxypropylmethyldimethoxysilane, γ-acryloxypropyltrimethoxysilane, γ-acryloxypropylmethyldimethoxysilane, N-(β-aminoethyl)-γ-aminopropyltrimethoxysilane, N-(β-aminoethyl)-γ-aminopropylmethyldimethoxysilane, γ-aminopropyltriethoxysilane, and γ-glycidoxypropyltrimethoxysilane.

Among them, as a silane coupling agent, an alkoxysilane containing an amino group is preferable, because the adhesive property is improved and an lamination procedure with a substrate such as glass or a back sheet may be carried out stably.

Specific examples of an alkoxysilane containing an amino group to be mixed in the ethylene type zinc ionomer include amino-trialkoxysilanes, such as 3-aminopropyltrimethoxyxysilane, 3-aminopropyltriethoxysilane, and N-(2-aminoethyl)-3-aminopropyltrimethoxyxysilane, and amino-dialkoxysilanes, such as N-(2-aminoethyl)-3-aminopropylmethyldimethoxysilane, N-(2-aminoethyl)-3-aminopropylmethyldiethoxysilane, N-(2-aminoethyl)-3-aminopropyldimethoxysilane, 3-aminopropylmethyldimethoxysilane, 3-aminopropylmethyldiethoxysilane, N-phenyl-3-aminopropylmethyldimethoxysilane, N-phenyl-3-aminopropylmethyldiethoxysilane, 3-methyldimethoxysilyl-N-(1,3-dimethyl-butylidene)propylamine, and 3-methyldimethoxysilyl-N-(1,3-dimethyl-butylidene)propylamine

Among them, N-(2-aminoethyl)-3-aminopropylmethyldimethoxysilane, N-(2-aminoethyl)-3-aminopropylmethyldiethoxysilane, N-(2-aminoethyl)-3-aminopropylethyldimethoxysilane, 3-aminopropylmethyldimethoxysilane, 3-aminopropylmethyldiethoxysilane and the like are preferable. Especially preferable is N-(2-aminoethyl)-3-aminopropylmethyldimethoxysilane.

Use of a dialkoxysilane is more preferable, because better fabrication stability at sheet forming can be maintained.

A silane coupling agent (especially, an alkoxysilane having an amino group) is mixed in an (A) layer at a rate of 3 parts by mass or less with respect to 100 parts by mass of the ethylene type zinc ionomer, preferably from 0.03 to 3 parts by mass, and especially from 0.05 to 1.5 parts by mass, from viewpoints of improving activity on the adhesive property and the fabrication stability at sheet forming In case a silane coupling agent is contained in the above range, the adhesive property between a multilayer sheet and a protective material or a solar cell element may be improved.

Various additives may be added to an (A) layer to the extent that the object of the present invention should not be impaired. Examples of such additives include an ultraviolet absorber, a light stabilizer, and an antioxidant.

In order to prevent deterioration of a multilayer sheet by exposure to ultraviolet rays, it is preferable to add an ultraviolet absorber, a light stabilizer, an antioxidant and the like to the ethylene type zinc ionomer.

Examples of an ultraviolet absorber to be used include a benzophenone type, such as 2-hydroxy-4-methoxybenzophenone, 2,2′-dihydroxy-4-methoxybenzophenone, 2-hydroxy-4-methoxy-2-carboxybenzophenone and 2-hydroxy-4-n-octoxybenzophenone; a benzotriazole type, such as 2-(2′-hydroxy-3′,5′-di-t-butylphenyl)benzotriazole, 2-(2′-hydroxy-5-methylphenyl)benzotriazole and 2-(2′-hydroxy-5-t-octylphenyl)benzotriazole; and a salicylic acid ester type, such as phenyl salicylate and p-octylphenyl salicylate.

As a light stabilizer, a hindered amine type is used. Example of the hindered amine type light stabilizer include 4-acetoxy-2,2,6,6-tetramethylpiperidine, 4-stearoyloxy-2,2,6,6-tetramethylpiperidine, 4-acryloyloxy-2,2,6,6-tetramethylpiperidine, 4-benzoyloxy-2,2,6,6-tetramethylpiperidine, 4-cyclohexanoyloxy-2,2,6,6-tetramethylpiperidine, 4-(o-chlorobenzoyloxy)-2,2,6,6-tetramethylpiperidine, 4-(phenoxyacetoxy)-2,2,6,6-tetramethylpiperidine, 1,3,8-triaza-7,7,9,9-tetramethyl-2,4-dioxo-3-n-octyl-spiro[4,5]decane, bis(2,2,6,6-tetramethyl-4-piperidyl)sebacate, bis(2,2,6,6-tetramethyl-4-piperidyl)terephthalate, bis(1,2,2,6,6-pentamethyl-4-piperidyl)sebacate, tris(2,2,6,6-tetramethyl-4-piperidyl)benzene-1,3,5-tricarboxylate, tris(2,2,6,6-tetramethyl-4-piperidyl)-2-acetoxy propane-1,2,3-tricarboxylate, tris(2,2,6,6-tetramethyl-4-piperidyl)-2-hydroxypropane-1,2,3-tricarboxylate, tris(2,2,6,6-tetramethyl-4-piperidyl)triazine-2,4,6-tricarboxylate, tris(2,2,6,6-tetramethyl-4-piperidine)phosphite, tris(2,2,6,6-tetramethyl-4-piperidyl)butane-1,2,3-tricarboxylate, tetrakis(2,2,6,6-tetramethyl-4-piperidyl)propane-1,1,2,3-tetracarboxylate, and tetrakis(2,2,6,6-tetramethyl-4-piperidyl)butane-1,2,3,4-tetracarboxylate.

Various hindered phenol type and phosphite type antioxidants are used. Specific examples of the hindered phenol type antioxidant may include 2,6-di-t-butyl-p-cresol, 2-t-butyl-4-methoxyphenol, 3-t-butyl-4-methoxyphenol, 2,6-di-t-butyl-4-ethylphenol, 2,2′-methylene-bis(4-methyl-6-t-butylphenol), 2,2′-methylenebis(4-ethyl-6-t-butylphenol), 4,4′-methylenebis(2,6-di-t-butylphenol), 2,2′-methylenebis[6-(1-methylcyclohexyl)-p-cresol], bis[3,3-bis(4-hydroxy-3-t-butylphenyl)butyric acid]glycol ester, 4,4′-butylidenebis(6-t-butyl-m-cresol), 2,2′-ethylidenebis(4-sec-butyl-6-t-butylphenol), 2,2′-ethylidenebis(4,6-di-t-butylphenol), 1,1,3-tris(2-methyl-4-hydroxy-5-t-butylphenyl)butane, 1,3,5-tris(3,5-di-t-butyl-4-hydroxybenzyl)-2,4,6-trimethylbenzene, 2,6-diphenyl-4-octadecyloxyphenol, tetrakis[methylene-3-(3,5-di-t-butyl-4-hydroxyphenyl)propionate]methane, n-octadecyl-3-(3,5-di-t-butyl-4-hydroxyphenyl)propionate, 4,4′-thiobis(6-t-butyl-m-cresol), tocopherol, 3,9-bis[1,1-dimethyl-2-[β-(3-t-butyl-4-hydroxy-5-methylphenyl)propionyloxy]ethyl]2,4,8,10-tetraoxaspiro[5,5]undecane, and 2,4,6-tris(3,5-di-t-butyl-4-hydroxybenzylthio)-1,3,5-triazine.

Meanwhile, specific examples of the phosphite type antioxidant may include 3,5-di-t-butyl-4-hydroxybenzylphosphanate dimethyl ester, ethyl bis(3,5-di-t-butyl-4-hydroxybenzylphosphonate, and tris(2,4-di-t-butylphenyl)phosphanate

An antioxidant, a light stabilizer, and an ultraviolet absorber may be added usually in amounts of respectively 5 parts by mass or less, preferably from 0.1 to 3 parts by mass, with respect to 100 parts by mass of the ethylene type zinc ionomer.

Further, in an (A) layer, an additive, such as a colorant, a light diffusing agent, a flame retarding agent, and a metal deactivating agent, may be added according to need in addition to the aforedescribed additives.

Examples of the colorant include a pigment, an inorganic compound, a dye and the like. Especially, examples of a white colorant include titanium oxide, zinc oxide, and calcium carbonate. In case a multilayer sheet containing such a colorant is used as an encapsulant on the light receiving side of a solar cell element, the transparency may be deteriorated. However, in case the same is used as an encapsulant on the opposite side to the light receiving side of the solar cell element, it may be used favorably.

Examples of the light diffusing agent include an inorganic spherical substance, such as glass beads, silica beads, silicon alkoxide beads, and hollow glass beads. Further, examples of an organic spherical substance include plastic beads of an acrylic type and a vinyl benzene type.

Examples of the flame retarding agent include a halogen-based flame retarding agent, such as a bromide, a phosphorus-based flame retarding agent, a silicone-based flame retarding agent, and a metal hydrate, such as magnesium hydroxide and aluminum hydroxide.

As the metal deactivating agent, a commonly known compound for suppressing metallic damages on a thermoplastic resin may be used. Two or more metal deactivating agents may be used in combination. Examples of a preferable metal deactivating agent include a hydrazide derivative, and a triazole derivative. More specifically, preferable examples of a hydrazide derivative include decamethylene dicarboxyl-disalicyloyl hydrazide, 2′,3-bis[3-[3,5-di-tert-butyl-4-hydroxyphenyl]propionyl]propionohydrazide, and isophthalic acid bis(2-phenoxypropionyl-hydrazide), and preferable examples of a triazole derivative include 3-(N-salicyloyl)amino-1,2,4-triazole. Examples of other than a hydrazide derivative, and a triazole derivative include 2,2′-dihydroxy-3,3′-di-(α-methylcyclohexyl)-5,5′-dimethyldiphenylmethane, tris-(2-methyl-4-hydroxy-5-tert-butylphenyl)butane, and a mixture with 2-mercaptobenzimidazole and a condensation product of phenol.

The (B) layer constituting a multilayer sheet according to the present invention contains as a resin material a polyethylene-based copolymer having the melting point of 90° C. or higher as the main component. The expression “contains . . . as the main component” means herein that the ratio occupied by “a polyethylene-based copolymer” is 80% by mass or more with respect to the total mass of the (B) layer.

In case the melting point of a resin material constituting the (B) layer is 90° C. or higher, the multilayer sheet may be used satisfactorily as a solar cell sealing sheet. However, if especially high heat resistance or durability is required, a resin material having a higher melting point, for example a melting point of 100° C. or higher, should preferably be selected.

Examples of the polyethylene-based copolymer having the melting point of 90° C. or higher, which is the main component of the (B) layer, include an ethylene/vinyl acetate copolymer, an ethylene/acrylic acid ester copolymer, an ethylene/unsaturated carboxylic acid copolymer and an ionomer thereof, high pressure low density polyethylene, an ethylene/α-olefin-based copolymer and the like.

In the ethylene/vinyl acetate copolymer, a ratio of the constituent unit derived from ethylene should preferably be from 85% to 99% by mass, and more preferably from 88% to 99% by mass. On the other hand, a ratio of the constituent unit derived from vinyl acetate should preferably be from 1% to 15% by mass, and more preferably from 1% to 12% by mass. In case the ratio of the constituent unit derived from ethylene is 85% by mass or more, the heat resistance of the copolymer is superior.

The ethylene/vinyl acetate copolymer with the melt flow rate (MFR: according to JIS K7210-1999, 190° C., 2160 g) of from 0.1 to 150 g/10 min, and especially from 0.1 to 50 g/10 min is preferably used, if the processability and mechanical strength were considered.

Examples of an ethylene/acrylic acid ester copolymer include, with respect to a type of the acrylic acid ester, those copolymerized with a (meth)acrylic acid ester, such as methyl acrylate, ethyl acrylate, isobutyl acrylate, n-butyl acrylate, 2-ethylhexyl acrylate, methyl methacrylate, and isobutyl methacrylate.

For an ethylene/acrylic acid ester copolymer, a ratio of the constituent unit derived from ethylene should preferably be from 85% to 99% by mass, and more preferably from 88% to 99% by mass. On the other hand, a ratio of the constituent unit derived from an acrylic acid ester should preferably be from 1% to 15% by mass, and more preferably from 1% to 12% by mass. In case the ratio of the constituent unit derived from ethylene is 85% by mass or more, the heat resistance of the copolymer is superior.

The ethylene/acrylic acid ester copolymer with the melt flow rate (MFR: according to JIS K7210-1999, 190° C., 2160 g) of from 0.1 to 150 g/10 min, and especially from 0.1 to 50 g/10 min is preferably used, if the processability and mechanical strength were considered.

Examples of an ethylene/unsaturated carboxylic acid copolymer and an ionomer thereof include, with respect to a type of the unsaturated carboxylic acid, those copolymerized with acrylic acid, methacrylic acid, maleic acid, maleic anhydride, and maleic anhydride monoester, and especially those copolymerized with acrylic acid or methacrylic acid are preferable. Examples of an especially preferable ionomer include zinc ionomers of an ethylene/acrylic acid copolymer or an ethylene/methacrylic acid copolymer.

In the ethylene/unsaturated carboxylic acid copolymer and an ionomer thereof, a ratio of the constituent unit derived from ethylene should preferably be from 15% to 99% by mass, and more preferably 88% to 99% by mass. On the other hand, a ratio of the constituent unit derived from an unsaturated carboxylic acid should preferably be from 1% to 15% by mass, and more preferably from 1% to 12% by mass. In case the ratio of the constituent unit derived from ethylene is 15% by mass or more, the heat resistance of the copolymer is superior.

The ethylene/unsaturated carboxylic acid copolymer and an ionomer thereof with the melt flow rate (MFR: according to JIS K7210-1999, 190° C., 2160 g) of from 0.1 to 150 g/10 min, and especially from 0.1 to 50 g/10 min is preferably used, if the processability and mechanical strength were considered.

The high pressure low density polyethylene with the melt flow rate (MFR: according to JIS K7210-1999, 190° C., 2160 g) of from 0.1 to 150 g/10 min, and especially from 0.1 to 50 g/10 min is preferably used, if the processability and mechanical strength were considered.

The ethylene/vinyl acetate copolymer, the ethylene/acrylic acid ester copolymer, the high pressure low density polyethylene, and the ethylene/unsaturated carboxylic acid copolymer may be produced by a heretofore publicly known method, such as a high pressure autoclave process or tubular process.

An ethylene/α-olefin-based copolymer is preferably a polymer that a content ratio of the constituent unit derived from α-olefin having 3 to 20 carbon atoms is preferably 5 mol % or more, and more preferably 10 mol % or more, based on total 100 mol % of all the constituent units (monomer units) constituting the copolymer. In case the content ratio of the constituent unit derived from the α-olefin is in the aforedescribed range, the transparency and bleeding resistance are superior. Especially, considering the flexibility, use of a polymer containing the constituent unit at 15 mol % or more is preferable.

Specific examples of the α-olefin having 3 to 20 carbon atoms include a linear α-olefin, such as propylene, 1-butene, 1-pentene, 1-hexene, 1-heptene, 1-octene, 1-nonene, 1-decene, 1-undecene, 1-dodecene, 1-tridecene, 1-tetradecene, 1-pentadecene, 1-hexadecene, 1-heptadecene, 1-octadecene, 1-nanodecene, and 1-eicosene; and a branched α-olefin, such as 3-methyl-1-butene, 3-methyl-1-pentene, 4-methyl-1-pentene, 2-ethyl-1-hexene, 2,2,4-trimethyl-1-pentene and the like, and two of which may be used in combination.

Among them, the carbon number of the α-olefin is preferably 3 to 10, and more preferably 3 to 8 in view of broader usage (cost and mass productivity).

As an ethylene/α-olefin copolymer, from a viewpoint of heat resistance, preferable are an ethylene/propylene copolymer (i.e. an ethylene/propylene copolymer with the ratio of a constituent unit derived from ethylene of 50 mol % or more), an ethylene/1-butene copolymer (i.e. an ethylene/1-butene copolymer with the ratio of a constituent unit derived from ethylene of 50 mol % or more), propylene/ethylene copolymer (i.e. a propylene/ethylene copolymer with the ratio of a constituent unit derived from propylene of 50 mol % or more), a propylene/1-butene copolymer (i.e. a propylene/1-butene copolymer with the ratio of a constituent unit derived from propylene of 50 mol % or more), a copolymer of an α-olefin other than ethylene and propylene with propylene and ethylene, and a propylene/1-hexene copolymer. The ethylene/α-olefin copolymer are more preferable, from the same reason, an ethylene/propylene copolymer, an ethylene/1-butene copolymer, a propylene/1-butene copolymer, a propylene/1-hexene copolymer, a propylene/ethylene/1-butene copolymer, and a propylene/ethylene/1-hexene copolymer; further preferable are an ethylene/propylene copolymer, an ethylene/1-butene copolymer, and a propylene/1-butene copolymer; especially preferable are an ethylene/propylene copolymer, and ethylene/1-butene copolymer; and most preferable is an ethylene/propylene copolymer.

For a solar cell sealing sheet, one of the ethylene/α-olefin copolymers may be used singly, or 2 or more of them may be used in combination.

An ethylene/α-olefin copolymer with the aforedescribed properties may be produced using a metallocene catalyst by a slurry polymerization process, a solution polymerization process, a bulk polymerization process, a gas phase polymerization process or the like. Examples of the catalyst include metallocene catalysts disclosed by Japanese Patent Laid-Open No. 58-19309, Japanese Patent Laid-Open No. 60-35005, Japanese Patent Laid-Open No. 60-35006, Japanese Patent Laid-Open No. 60-35007, Japanese Patent Laid-Open No. 60-35008, Japanese Patent Laid-Open No. 61-130314, Japanese Patent Laid-Open No. 3-163088, Japanese Patent Laid-Open No. 4-268307, Japanese Patent Laid-Open No. 9-12790, Japanese Patent Laid-Open No. 9-87313, Japanese Patent Laid-Open No. 10-508055, Japanese Patent Laid-Open No. 11-80233, and Japanese National Publication of International Patent Application No. 10-508055. Especially preferable example of a production process using a metallocene catalyst includes a process according to EP Patent Application No. 1211287(A1).

An ethylene/α-olefin copolymer may be produced by copolymerizing ethylene and another α-olefin in the presence of, not only a metallocene catalyst, but also, in case of a copolymer containing ethylene as a main component, a vanadium catalyst composed of a soluble vanadium compound and an organic aluminum halide, or in the presence of a metallocene catalyst composed of a metallocene compound such as a zirconium compound coordinated with a cyclopentadienyl group and the like and an organic aluminumoxy compound. In case of a copolymer containing propylene as a main component, it may be produced by copolymerizing propylene and another α-olefin in the presence of a transition metal compound component, such as a high activity titanium catalyst component, a metallocene-based catalyst component or the like, an organic aluminum component, and a stereoregular olefin polymerization catalyst containing according to need an electron donor, a carrier or the like.

The ethylene/α-olefin copolymer with the melt flow rate (MFR: measured according to ASTM D-1238, at 230° C., 2160 g) of from 0.1 to 150 g/10 min, and especially from 0.5 to 20 g/10 min is preferably used, if the processability and mechanical strength were considered.

Various additives may be added into the (B) layer to the extent that the object of the present invention should not be impaired. Examples of such additives include all the aforedescribed additives that may be added to the (A) layer. Further, the additives may be added to the (B) layer in the same amount as they are added to an (A) layer.

In the present invention, a silane coupling agent may be contained in the (B) layer together with in an (A) layer and may be contained in both the (A) layer and (B) layer. In the present invention, it is preferable that the content ratio of a silane coupling agent in the (B) layer with respect to a resin material (including a polyethylene-based copolymer with the melting point of 90° C. or higher) is less than the content ratio of a silane coupling agent in an (A) layer with respect to a resin material (including an ethylene type zinc ionomer). Particularly, more preferably, the content ratio of a silane coupling agent in a (B) layer is 50% or less than the content ratio of a silane coupling agent in an (A) layer, further preferably a (B) layer does not contain substantially a silane coupling agent (0.1% by mass or less with respect to a solid substance in a (B) layer), and especially preferably a (B) layer does not contain a silane coupling agent (0% by mass).

A multilayer sheet of the present invention includes an (A) layer containing an ethylene type zinc ionomer as the main component and a silane coupling agent, and a (B) layer containing a polyethylene-based copolymer with the melting point of 90° C. or higher as the main component, and the total thickness of the (A) layer and the (B) layer is from 0.1 to 2 mm. Preferably, the total thickness is from 0.2 to 1.5 mm. In case the total thickness of a multilayer sheet is 0 1 mm or more, it is suitable for sealing a solar cell element and an interconnection, and in case the total thickness is 2 mm or less, the transparency of the multilayer sheet becomes superior, which is good for designing.

The (A) layer has preferably a structure constituted with a single layer of an ethylene type zinc ionomer as the main component, however it may be constituted with a plurality of layers, in which the compositions of the ethylene type zinc ionomers or the content ratios of another copolymerizable monomer contained in ethylene/unsaturated carboxylic acid copolymers (preferably ethylene/(meth)acrylic acid copolymers) are different respectively.

(A) layer(s) is (are) laminated on one or both side(s) of a (B) layer. The (B) layer has preferably, similarly as an (A) layer, a structure constituted with a single layer, however it may have a laminate structure, in which a plurality of layers containing different polyethylene-based copolymers as the main components are laminated.

As described above, a multilayer sheet is preferably constituted with a plurality of layers of (A) layer(s) and (B) layer(s), especially preferable a 3-layer sheet constituted with a middle layer composed of a (B) layer and outer layers composed of (A) layers sandwiching the middle layer from both the sides, or a 2-layer sheet containing an (A) layer and a (B) layer.

The ratio (a/b) of the thickness (a) of an (A) layer to the thickness (b) of a (B) layer, respectively constituting a multilayer sheet, is from 20/1 to 1/20, preferably from10/1 to 1/10. In case the the ratio (a/b) of the thicknesses of the (A) layer and the (B) layer is in the above range, a multilayer sheet superior in the adhesive property, heat resistance, durability, and cost reduction, and suitable for use for a solar cell module, may be obtained.

A multilayer sheet of the present invention may be formed by a publicly known method using a monolayer or multilayer T-die extruder, a calendar molding machine, or a monolayer or a multilayer inflation molding machine or the like. For example, to each of an ethylene-based ionomer and a polyethylene-based copolymer, an additive, such as an adhesion promoter, an antioxidant, a light stabilizer, and an ultraviolet absorber, is added according to need and dry-blended. The multilayer sheet is obtained by supplying the mixture through hoppers to a main extruder and a sub-extruder of a multilayer T-die extruder and forming into a sheet shape by multilayer extrusion.

A multilayer sheet of the present invention is suitable for an encapsulant for a solar cell element to be described below, and among others suitable for use for sealing an amorphous silicon solar cell element.

[Solar Cell Module]

A solar cell module of the present invention is produced by fixing the upper side and the lower side of a solar cell element by protective materials. Examples of a solar cell module of the present invention include a constitution in which a solar cell element is sandwiched by multilayer sheets from both sides, e.g. upper transparent protective material/multilayer sheet/solar cell element/multilayer sheet/lower protective material; and a solar cell element formed on an inner surface of an upper transparent protective material, e.g. a constitution in which a multilayer sheet and a lower protective material are formed on an amorphous solar cell element produced by sputtering and the like on a glass, or fluorocarbon resin sheet. In case a multilayer sheet of the present invention has a 3-layer structure of (B) layer/(A) layer/(B) layer, the solar cell module is so laminated that one of the (B) layers forming an outer layer contacts a solar cell element, and the other (B) layer forming the other outer layer contacts an upper transparent protective material or a lower protective material. On the other hand, in case a multilayer sheet of the present invention has a 2-layer structure of (A) layer/(B) layer, the module is so laminated that the (A) layer contacts the solar cell element, and the (B) layer contacts an upper protective material or a lower protective material (back sheet).

An encapsulant for solar cell element of the present invention having a multilayer sheet containing a (B) layer using a polyethylene-based copolymer is superior in moisture resistance. In general, a thin film type solar cell tends to be susceptible to moisture, because a metallic film electrode deposited on a substrate is used. Consequently, a configuration, in which an encapsulant for solar cell element of the present invention is applied to a thin film solar cell, is one of preferable embodiments. More specifically, application to a thin film solar cell with the constitution in which an encapsulant sheet (an encapsulant for solar cell element) and a lower protective material are formed on a solar cell element formed on an inner surface of an upper transparent protective material is one of preferable embodiments.

Examples of the solar cell element include a group IV semiconductor, such as monocrystalline silicon, polycrystalline silicon, amorphous silicon or the like; and a group III-V and group II-VI compound semiconductor, such as gallium-arsenic, copper-indium-selenium, copper-indium -gallium-selenium, cadmium-tellurium or the like.

### EXAMPLES

The present invention will be described below more specifically by way of examples, provided that the present invention should not be construed to be limited to the following examples, without departing from the spirit of the invention. The term “part(s)” is based on mass unless otherwise specified.

Materials, compounds for respective layers, substrates, and evaluation methods to be used in the following Examples and Comparative Examples are as follows:

### (1) Resins

1. Resin materials for (A) Layer

Ionomer 1: A zinc ionomer (degree of neutralization 17%, MFR 5.5 g/10 min, melting point 98° C.) of an ethylene/methacrylic acid copolymer (methacrylic acid unit content=8.5% by mass)

Ionomer 2: A zinc ionomer (degree of neutralization 28%, MFR 9 g/10 min) of an ethylene/methacrylic acid/isobutyl acrylate terpolymer (methacrylic acid unit content=10% by mass, isobutyl acrylate unit content=10% by mass)

### 2. Resin Materials for (B) Layer

EVA: An ethylene/vinyl acetate copolymer (vinyl acetate 6% by mass, MFR 7.5 g/10 min, melting point 94° C.)

EMAA: An ethylene/methacrylic acid copolymer (methacrylic acid 4% by mass, MFR 7 g/10 min, melting point 103° C.)

PE: A polyethylene copolymer (Evolue SP 1071 C, manufactured by Mitsui Chemicals, Inc. (8.6 g/10 min, melting point 110° C.); ethylene/1-hexene copolymer)

Ionomer 1: A zinc ionomer (degree of neutralization 17%, MFR 5.5 g/10 min, melting point 98° C.) of an ethylene/methacrylic acid copolymer (methacrylic acid unit content 8.5% by mass)

Ionomer 3: A zinc ionomer (degree of neutralization 23%, MFR 5 g/10 min, melting point 91° C.) of an ethylene/methacrylic acid copolymer (methacrylic acid unit content 15% by mass)

(2) Additives

Antioxidant: Irganox 1010 (manufactured by Ciba Inc.)

Ultraviolet absorber: 2-hydroxy-4-n-octoxybenzophenone

Light stabilizer: bis(2,2,6,6-tetramethyl-4-piperidyl)sebacate

Silane coupling agent: N-(2-aminoethyl)-3-aminopropylmethyldimethoxysilane

Also, the ultraviolet absorber and the light stabilizer were used as a stabilizer masterbatch, which was prepared by making of the ultraviolet absorber, the light stabilizer and a resin same as the resin to be used in the relevant layer at the mass ratio of resin/UV absorber/light stabilizer=95.5/3/1.5 in a twin screw extruder.

(3) Compounds

Compounding of each layer was carried out by mixing at the following ratio in advance. In case a silane coupling agent is mixed, the mixing is carried out in a polyethylene bag followed by shaking in a tumbler for 30 min or longer.

[(A) Layer]

(A)-1: ionomer 1/stabilizer masterbatch/antioxidant/silane coupling agent=96/4/0.03/0.2

(A)-2: ionomer 2/stabilizer masterbatch/antioxidant/silane coupling agent=96/4/0.03/0.4

(A)-3: ionomer 1/EMAA/stabilizer masterbatch/antioxidant/silane coupling agent=66/30/4/0.03/0.4

### [(B) Layer]

(B)-1: EVA/stabilizer masterbatch/antioxidant=96/4/0.03

(B)-2: EMAA/stabilizer masterbatch/antioxidant=96/4/0.03

(B)-3: PE/stabilizer masterbatch/antioxidant=96/4/0.03

(B)-4: ionomer 1/stabilizer masterbatch/antioxidant=96/4/0.03

(B)-5: ionomer 3/stabilizer masterbatch/antioxidant=96/4/0.03

(4) Substrates

i) 3.9 mm of float glass (manufactured by Asahi Glass Co., Ltd.)

ii) 3.2 mm of tempered float glass (manufactured by Asahi Glass Co., Ltd.)

iii) 3.2 mm of non-iron tempered glass (white heat-treated plate glass) (manufactured by Asahi Glass Co., Ltd.)

iv) Back sheet: ALTD700 (manufactured by MA Packaging Co., Ltd.)

(5) Evaluations

Evaluation methods for multilayer sheets produced in the following Examples and Comparative Examples are shown below.

i) Interlayer Adhesive Strength

The adhesive strength between the layers of a multilayer sheet was measured by actual peeling. Measurement was carried out using the width of 15 mm at the drawing speed of 300 mm/min.

ii) Adhesive Strength

Using a 3.9 mm-thick of the float glass (75 mm×120 mm) and the back sheet as well as a 0.4 mm-thick of multilayer sheet, sample with a constitution of float glass/multilayer sheet, or float glass/multilayer sheet/back sheet were prepared by a vacuum heating laminator (LM-50×50S, manufactured by NPC Corp) under the conditions of 150° C., for 6 min. With respect to the samples, the adhesive strengths between the glass and the multilayer sheet, and between the multilayer sheet and the back sheet were measured, and the maximum values thereof were adopted as evaluation indicators for adhesive strengths. The measurements were carried out using the width of 15 mm at the drawing speed of 100 mm/min.

iii) Transparency

Using a 3.2 mm-thick of the tempered float glass (75 mm×120 mm) and a 0.4 mm-thick multilayer sheet, a sample with a constitution of glass/multilayer sheet/glass was prepared by a vacuum heating laminator (LM-50×50S, manufactured by NPC Corp) under the conditions of 150° C., for 6 min. With respect to the sample, the light transmission was measured by a haze meter (manufactured by Suga Test Instruments Co., Ltd.) according to JIS-K7105 and the measured value was adopted as an evaluation indicator for transparency.

iv) Heat Resistance (Dislocation of Cell)

Using a 3.2 mm-thick of the non-iron tempered glass (250 mm×250 mm) and a multilayer sheet, a polycrystalline silicon cell (PWP4CP3, manufactured by Photowatt Technologies, 101 mm×101 mm, polycrystalline silicon cell, thickness 250 μm), the multilayer sheet, and the back sheet were piled in the order mentioned and laminated by a vacuum heating laminator (LM-50×50S, manufactured by NPC Corp) under the conditions of 150° C., for 6 min to prepare a sample. The sample was subjected to the inclination of 60° in an oven at 100° C. for 8 hours and examined if displacement of the silicon cell took place.

v) Heat Resistance (Pressure Cooker Test: PCT)

Each multilayer sheet prepared in the following Examples 1, 3, 7, and Comparative Example 1 was sandwiched by 2 sheets of 3.2 mm-float glass (120 mm×75 mm) and laminated by a vacuum heating laminator (LM-50×50S, manufactured by NPC Corp) under the conditions of 170° C., for 10 min to prepare a sample constituted with glass. Each sample was subjected to a treatment under the conditions of 105° C., 100% RH, 0.12 MPa for 12 hours in an autoclave (Model MCS-23, manufactured by ALP Co., Ltd.) and examined if appearance change (bubbling) took place. The results are shown in the following Table 2.

(6) Preparation of Multilayer Sheet

A multilayer sheet was produced by the following forming machines. All of the following forming machines were 40 mmΦ single screw extruders and the die width was 500 mm.

A multilayer casting mold machine (3-layer multilayer of three resin) : manufactured by Tanabe Plastics Machinery Co. Ltd.

Coextrusion feed block: manufactured by Extrusion Dies Industries, LLC

### Example 1

Using (A)-1 as outer layers and (B)-2 as a middle layer, a multilayer sheet with the thickness ratio (outer layer 1/middle layer/outer layer 2)=1/2/1, the total thickness of 400 μm (0.4 mm) was produced by the multilayer casting machine at the resin temperature of 180° C. Various evaluations of the multilayer sheet were carried out. The results are shown in the following Table 1.

### Example 2

A multilayer sheet was produced in the same manner as in Example 1, except that (B)-1 was substituted for (B)-2 used as a middle layer and the thickness ratio (outer layer 1/middle layer/outer layer 2)=1/4/1 (total thickness=0.4 mm) was selected in Example 1, and various evaluations were also performed. The results are shown in the following Table 1.

### Example 3

A multilayer sheet was produced in the same manner as in Example 1, except that (B)-3 was substituted for (B)-2 used as a middle layer in Example 1, and various evaluations were also performed. The results are shown in the following Table 1.

### Example 4

A multilayer sheet was produced in the same manner as in Example 1, except that (B)-4 was substituted for (B)-2 used as a middle layer in Example 1 (total thickness=0.4 mm), and various evaluations were also performed. The results are shown in the following Table 1.

### Example 5

A multilayer sheet was produced in the same manner as in Example 1, except that (A)-2 was substituted for (A)-1 used as a outer layer and (B)-4 was substituted for (B)-2 used as a middle layer in Example 1 (total thickness=0.4 mm), and various evaluations were also performed. The results are shown in the following Table 1.

### Example 6

A multilayer sheet was produced in the same manner as in Example 1, except that (A)-2 was substituted for (A)-1 used as a outer layer and (B)-5 was substituted for (B)-2 used as a middle layer in Example 1 (total thickness=0.4 mm), and various evaluations were also performed. The results are shown in the following Table 1.

### Example 7

A multilayer sheet was produced in the same manner as in Example 1, except that (A)-3 was substituted for (A)-1 used as a outer layer in Example 1 (total thickness=0.3 mm), and various evaluations were also performed. The results are shown in the following Table 1.

### Comparative Example 1

For all of the outer layer 1, outer layer 2, and middle layer in Example 1, (A)-1 was used to produce a single layer sheet constituted with (A)-1 (thickness=0.4 mm). The forming conditions were same as in Example 1, and various evaluations were carried out as in Example 1. The results are shown in the following Table 1.

### Comparative Example 2

For all of the outer layer 1, outer layer 2, and middle layer in Example 1, (A)-2 was used to produce a single layer sheet constituted with (A)-2 (thickness=0.4 mm). The forming conditions were same as in Example 1, and various evaluations were carried out as in Example 1. The results are shown in the following Table 1.

TABLE 1

| | | | | Layer | | Glass | | | |
|---|---|---|---|---|---|---|---|---|---|
| | | | | thickness ratio | Interlayer | adhesive | Back sheet | | Transparency |
| | (A) Layer | (B) Layer | (A) Layer | [Outer layer 1/ | adhesive | strength | adhesive strength | Heat | [Light |
| | [Outer | [Middle | [Outer | Middle layer/ | strength | (Maximum) | (Maximum) | resistance | transmission; |
| | layer 1] | layer] | layer 2] | Outer layer 2] | [N/15 mm] | [N/15 mm] | [N/15 mm] | [Cell dislocation] | %] |
| Example 1 | (A)-1 | (B)-2 | (A)-1 | 1/2/1 | Not | 58 | >20 | nil | 85.1 |
| | | | | | peelable | | Substrate failure | | |
| | | | | | | | (cohesive failure) | | |
| Example 2 | (A)-1 | (B)-1 | (A)-1 | 1/4/1 | Not | 55 | >20 | nil | 85.2 |
| | | | | | peelable | | Substrate failure | | |
| | | | | | | | (cohesive failure) | | |
| Example 3 | (A)-1 | (B)-3 | (A)-1 | 1/2/1 | Not | 49 | >20 | nil | 86.9 |
| | | | | | peelable | | Substrate failure | | |
| | | | | | | | (cohesive failure) | | |
| Example 4 | (A)-1 | (B)-4 | (A)-1 | 1/2/1 | 18 | 55 | >20 | nil | 86.9 |
| | | | | | | | Substrate failure | | |
| | | | | | | | (cohesive failure) | | |
| Example 5 | (A)-2 | (B)-4 | (A)-2 | 1/2/1 | Not | 43 | >20 | nil | 88.3 |
| | | | | | peelable | | Substrate failure | | |
| | | | | | | | (cohesive failure) | | |
| Example 6 | (A)-2 | (B)-5 | (A)-2 | 1/2/1 | Not | 47 | >20 | nil | 89.9 |
| | | | | | peelable | | Substrate failure | | |
| | | | | | | | (cohesive failure) | | |
| Example 7 | (A)-3 | (B)-2 | (A)-3 | 1/2/1 | Not | 44 | >20 | nil | 76.3 |
| | | | | | peelable | | Substrate failure | | |
| | | | | | | | (cohesive failure) | | |

| | | | | | | | |
|---|---|---|---|---|---|---|---|
| Comparative | (A)-1 | Single layer | Not | 54 | >20 | nil | 87 |
| Example 1 | | | peelable | | Substrate failure | | |
| | | | | | (cohesive failure) | | |
| Comparative | (A)-2 | Single layer | Not | 30 | >20 | nil | 88.8 |
| Example 2 | | | peelable | | Substrate failure | | |
| | | | | | (cohesive failure) | | |

TABLE 2

| | | | | Layer | |
|---|---|---|---|---|---|
| | (A) | (B) | (A) | thickness ratio | |
| | Layer | Layer | Layer | [Outer layer 1/ | |
| | [Outer | [Middle | [Outer | Middle layer/ | resistance test |
| | layer 1] | layer] | layer 2] | Outer layer 2] | to heat PCT |
| Example 1 | (A)-1 | (B)-2 | (A)-1 | 1/2/1 | No appearance |
| | | | | | change |
| Example 3 | (A)-1 | (B)-3 | (A)-1 | 1/2/1 | No appearance |
| | | | | | change |
| Example 7 | (A)-3 | (B)-2 | (A)-3 | 1/2/1 | No appearance |
| | | | | | change |

| | | | |
|---|---|---|---|
| Compara- | (A)-1 | Single | Bubbling |
| tive Ex- | | layer | occurred |
| ample 1 | | | |

Using the thus obtained multilayer sheet, glass/multilayer sheet/solar cell element/multilayer sheet/solar cell back sheet were piled in the order mentioned and pressed, so that a solar cell module may be prepared.

As obvious from Table 1 and Table 2, in Examples, multilayer sheets superior in adhesive strength, durability and heat resistance, and with suppressed costs were obtained.

### INDUSTRIAL APPLICABILITY

A multilayer sheet according to the present invention may be favorably utilized as an encapsulant for a solar cell element, and as a middle film for laminated glass for vehicles, ship and buildings.

The entire disclosure of Japanese Patent Application No. 2008-280518 is incorporated herein into this specification by reference.

All documents, patent applications and technical specifications recited in this specification are incorporated herein by reference in this specification to the same extent as if each individual publication, patent applications and technical standard was specifically and individually indicated to be incorporated by reference.

1-15. (canceled)

16. A solar cell module comprising a multilayer sheet having a three-layer structure, comprising two (A) layers comprising an ethylene-based zinc ionomer as a main component, an ethylene/unsaturated carboxylic acid copolymer, and a silane coupling agent, and a (B) layer disposed between the two (A) layers, the (B) layer comprising a polyethylene-based copolymer with a melting point of 90° C. or higher as a main component and substantially no silane coupling agent,
wherein a ratio (a/b) of the thickness (a) of the (A) layer to the thickness (b) of the (B) layer is from 20/1 to 1/20, and
a total thickness of the (A) layer and the (B) layer is from 0.1 to 2 mm.

17. The solar cell module according to claim 16, wherein the ethylene-based zinc ionomer in the (A) layer comprises an ionomer and a dialkoxy silane having an amino group in an amount of 3 parts by mass or less with respect to 100 parts by mass of the ionomer.

18. The solar cell module according to claim 16, wherein the melt flow rate (MFR:
JIS K7210-1999, 190° C., load 2160 g) of the ethylene-based zinc ionomer in the (A) layer and of the polyethylene-based copolymer with the melting point of 90° C. or higher in the (B) layer is from 0.1 to 150 g/10 min.

19. The solar cell module according to claim 16, wherein at least one of the (A) layer or the (B) layer further comprises one or more additive selected from an ultraviolet absorber, a light stabilizer, or an antioxidant.

20. The solar cell module according to claim 16, wherein the ethylene-based zinc ionomer is a zinc ionomer of an ethylene/unsaturated carboxylic acid copolymer having a constituent unit derived from ethylene and a constituent unit derived from an unsaturated carboxylic acid, wherein the content ratio of the constituent unit derived from ethylene is from 75 to 95% by mass, and the content ratio of the constituent unit derived from an unsaturated carboxylic acid is from 5 to 25% by mass.

21. The solar cell module according to claim 20, wherein the unsaturated carboxylic acid is acrylic acid or methacrylic acid.

22. The solar cell module according to claim 16, wherein the degree of neutralization of the ethylene-based zinc ionomer is from 5% to 60%.

23. The solar cell module according to claim 16, wherein the silane coupling agent is at least one selected from N-(2-aminoethyl)-3-aminopropylmethyldimethoxysilane, N-(2-aminoethyl)-3-aminopropylmethyldiethoxysilane, N-(2-aminoethyl)-3-aminopropylethyldimethoxy silane, 3-aminopropylmethyldimethoxysilane, or 3-aminopropylmethyldiethoxysilane.

24. The solar cell module according to claim 16, wherein the (A) layer contains the silane coupling agent in an amount in a range of from 0.03 to 3 parts by mass with respect to 100 parts by mass of the ethylene-based zinc ionomer.

25. The solar cell module according to claim 16, wherein the polyethylene-based copolymer is an ethylene/unsaturated carboxylic acid copolymer or an ionomer thereof.

26. The solar cell module according to claim 25, wherein the ionomer of an ethylene/unsaturated carboxylic acid copolymer is a zinc ionomer of an ethylene/acrylic acid copolymer or an ethylene/methacrylic acid copolymer.
